(19) United States
(12) Patent Application Publication
(10) Pub. No.: US 2022/0260212 A1
(43) Pub. Date: Aug. 18, 2022

(54) ACETYLENE FLUID SUPPLY PACKAGE, SYSTEM COMPRISING THE SAME AND METHOD OF FABRICATING SEMICONDUCTOR DEVICE USING THE SAME

(71) Applicants: Ashwini K. Sinha, East Amherst, NY (US); Xuemei Song, East Amherst, NY (US); William S. Kane, Tonawanda, NY (US); Youn-Joung Cho, Gyeonggi-do (KR); Wonwoong Chung, Gyeonggi-do (KR); Yeonock Han, Gyeonggi-do (KR)

(72) Inventors: Ashwini K. Sinha, East Amherst, NY (US); Xuemei Song, East Amherst, NY (US); William S. Kane, Tonawanda, NY (US); Youn-Joung Cho, Gyeonggi-do (KR); Wonwoong Chung, Gyeonggi-do (KR); Yeonock Han, Gyeonggi-do (KR)

(21) Appl. No.: 17/667,861

(22) Filed: Feb. 9, 2022

Related U.S. Application Data
(60) Provisional application No. 63/150,203, filed on Feb. 17, 2021.

(51) Int. Cl. F17C 11/00; F17C 7/00; C23C 16/26; H01L 21/762; H01L 21/02

(52) U.S. Cl. CPC F17C 11/002; F17C 7/00; C23C 16/26; F17C 2270/0518; H01L 21/02115; F17C 2221/018; H01L 21/762

(57) ABSTRACT

A composition comprising acetylene fluid at least partially solubilized in an improved solvent is described. The improved solvents exhibit non-toxicity and are further characterized by low vapor pressures to minimize solvent carryover during delivery of the acetylene fluid, while retaining suitable acetylene solubilizing capacity.

This application claims the benefit of priority to U.S. Provisional Application Ser. No. 63/150,203 filed on Feb. 17, 2021, the disclosure of which is incorporated herein by reference in its entirety for all purposes.

### TECHNICAL FIELD

The present inventive concept relates to novel compositions of improved solvents solubilized with acetylene fluid. Particularly, the improved solvents exhibit non-toxicity for acetylene fluid storage, dispensing and handling, and are furthermore characterized by low vapor pressures to minimize solvent carryover during delivery of the acetylene fluid, while retaining suitable acetylene solubilizing capacity.

### BACKGROUND

Acetylene is used widely in the industry for a variety of applications including, by way of example, welding and chemical synthesis. Of particular significance, acetylene has been used increasingly as a source material for depositing carbon and carbon-containing films in the electronic industry. Applications include the deposition of amorphous carbon hard mask films.

However, due to its thermal instability, the storage of acetylene has posed several challenges. Acetylene can decompose explosively into carbon and hydrogen under storage conditions of high pressure and temperature, even in the absence of air or oxygen.

To address the thermal instability, acetylene cylinders are constructed uniquely. Each cylinder contains a porous filler (e.g., silica) with a solvent that has typically included acetone, dimethylformamide (DMF) or N-methyl-2-pyrrolidone (NMP) distributed throughout the porous filler media. These solvents have been traditionally selected as a result of their capacity for solubilizing acetylene. The porous filler media is a porous mass generally having a porosity of around 90% by volume. The function of the porous filler media is to separate acetylene into small units in the pores that help to inhibit the decomposition of acetylene. The function of the solvent is to absorb large amounts of acetylene at relatively low pressures to enable high cylinder loading in low pressure cylinders. The solvent is dispersed in the voids of the porous filler media as well as around the porous filler media.

Despite improved thermal stability in such cylinder systems, the Applicants have discovered that specific modifications to the existing acetylene cylinder fluid supply packages results in improved storage, handling and delivery capabilities, as will now be explained.

### SUMMARY

In one aspect, an acetylene fluid supply package, comprising a pressure vessel; a porous filler in the pressure vessel; an improved solvent within the porous filler, said solvent solubilizing with acetylene absorbed within the improved solvent; said improved solvent comprising triethyl phosphate (TEP), said TEP loaded into the pressure vessel in an amount no greater than about 0.64 kg of TEP per liter of volume of the pressure vessel.

In a second aspect, a system comprising at least one acetylene fluid supply package and an acetylene-utilizing process tool in fluid communication with the at least one acetylene fluid supply package, said at least one acetylene fluid supply package, comprising a pressure vessel; a porous filler in the pressure vessel; an improved solvent within the porous filler, said solvent solubilizing with acetylene absorbed within the improved solvent; said improved solvent comprising triethyl phosphate (TEP), said TEP loaded into the pressure vessel in an amount no greater than about 0.64 kg of TEP per liter of volume of the pressure vessel. wherein the at least one acetylene fluid supply package is configured to allow a discharge of the acetylene fluid under dispensing conditions; and further wherein said acetylene-utilizing process tool is configured to receive the acetylene fluid from the at least one acetylene fluid supply package.

In a third aspect, a method of fabricating a semiconductor device, comprising providing a semiconductor substrate; and forming a carbon-containing layer on the semiconductor substrate using an acetylene fluid supply package, wherein the acetylene fluid supply package comprises a pressure vessel, a porous filler in the pressure vessel, and a solvent within the porous filler, said solvent solubilizing with acetylene absorbed within the solvent, the vapor pressure of the solvent is 6 torr or less at 20° C., the Hansen solubility factor (δh) of the solvent is 5 Mpa^{0.5} or more, and the reproductive toxicity of the solvent is lower than that of dimethylformamide (DMF).

### BRIEF DESCRIPTION OF THE DRAWINGS

The above and other aspects and features of the present inventive concept will become more apparent by describing in sufficient detail exemplary embodiments thereof with reference to the attached drawings, in which:

FIGS. 1 to 3 are schematic diagrams illustrating various acetylene fluid supply packages according to some embodiments.

FIG. 4 is a schematic diagram illustrating a deposition system including acetylene fluid supply packages according to some embodiments.

FIGS. 5 to 7 are graphs that illustrate the effect of the acetylene fluid supply packages according to some embodiments.

FIGS. 8 to 12 show intermediate steps of the method of fabricating a semiconductor device according to some embodiments.

FIGS. 13 to 19 show intermediate steps of the method of fabricating a semiconductor device according to some embodiments.

FIGS. 20 to 23 are drawings illustrating the intermediate steps of the method of fabricating a semiconductor device according to some embodiments.

FIG. 24 is an intermediate drawing for describing the method of fabricating a semiconductor device according to some embodiments.

### DETAILED DESCRIPTION OF THE EMBODIMENTS

The compositions, fluid supply packages and systems disclosed herein may comprise, consist, or consist essentially of any of the specific components and structures illustratively described herein. The disclosure further contemplates restrictively defined compositions, fluid supply packages, and systems, e.g., wherein one or more of the specifically described parts, components, and structures may be specifically omitted, in defining operative embodiments of the present disclosure.

The embodiments as described below are by way of example only, and the inventive concept is not limited to the embodiments illustrated in the drawings. It should also be understood that the drawings are for the purpose of illustrating the embodiments and are not intended to be drawn to scale and in certain instances details have been omitted, which are not necessary for an understanding of the embodiments.

As used herein and throughout, the term “fluid” is intended to include gases, vapors, liquids, and mixtures of the foregoing. “Acetylene fluid” as described herein and throughout is intended to mean substantially all of the acetylene is stored under pressure in the gas phase during storage in a container, but may incorporate a small amount of solvent carryover when the acetylene fluid is withdrawn from the container. The term “solvent” or “solvent fluid” is intended to substantially refer to the solvent in the liquid phase in substantial equilibrium with a corresponding vapor phase of relatively low vapor pressure.

“Container” or “cylinder”, or “package” or “delivery package” or “fluid supply package” any of which may be used herein and throughout interchangeably means any storage, filling, delivery or transportable vessel.

“Approximately” as used herein and throughout with respect to vapor pressure, means +/−3 torr.

The present inventive concept recognizes shortcomings of existing acetylene fluid supply packages. For example, the Applicants have observed that acetone when utilized as a solvent has an unacceptably high vapor pressure and therefore the acetone vapor can be withdrawn from the storage container and undesirably transported along with dispensed acetylene. The acetone solvent becomes a contaminant in acetylene for several applications such as deposition of carbon and carbon-containing films, including amorphous carbon hard mask films in the electronic industry. Thus, the acetone can ultimately reduce the film deposition rate and affect process uniformity and consistency.

To reduce contamination in those applications where solvent impurities cannot be tolerated in the resultant carbon-containing films derived from acetylene, alternative solvents with lower vapor pressure in comparison to acetone have been utilized for acetylene storage and delivery. For example, DMF and N-methyl-2-pyrrolidone (NMP) have been utilized as solvents, as part of acetylene fluid supply packages. However, both DMF and NMP exhibit toxicity. In particular, DMF and NMP pose risks of reproductive toxicity (i.e., teratogenicity). Because of such health risks, commercial usage of DMF and NMP has been restricted in several countries. Materials which pose a risk of reproductive toxicity are classified as having a H360 hazard statement code under the Globally Harmonized System of Classification and Labelling of Chemicals (GHS) It should be understood that toxicity as used herein refers to those materials which are classified as having a H360 hazard statement code.

Accordingly, given such drawbacks with the usage of traditional solvents in acetylene storage and delivery systems, Applicants have identified improved solvents that are a safer alternative to traditional solvents for storage and delivery of acetylene. A combination of certain attributes is required for the present inventive concept. The attributes of the improved solvents are characterized as having (i) a vapor pressure at 20 deg C. of approximately 6 torr or less; (ii) higher non-toxicity in comparison to dimethylformamide (DMF) and N-methyl-2-pyrrolidone (NMP); (iii) a chemical structure comprising at least one of-O, N or F atoms, wherein the at least one of said 0, N or F atoms is not bonded to a hydrogen atom, and further wherein said chemical structure is characterized by an absence of boron, calcium and nickel; and (iv) a Hansen solubility factor (δh) greater than about 5 MPa^{0.5}. The improved solvents by virtue of possessing the foregoing attributes can be used as part of an acetylene storage and delivery system, which do not exhibit a drop-off in acetylene solubilizing performance relative to traditional solvents.

Traditional solvents on the contrary, such as DMF and NMP, are generally classified as H360 under the global harmonized system of classification and labeling of chemicals (see Table 2 below). In other words, they pose a risk of reproductive toxicity and teratogenicity. The inventive solvents do not pose a risk of reproductive toxicity and, as such, are characterized by an absence of the H360 hazard statement code as classified by the GHS. The inventive solvents are generally more benign as a result of the absence of H360 classification.

In addition to the higher non-toxicity, the inventive solvents maintain sufficient solubility and interaction with acetylene. The Applicants have identified a combination of attributes necessary to provide effective solubility of the solvent within acetylene fluid. The solvent molecule and acetylene molecule attract each other such that at least a portion of the acetylene molecule can reside within the solvent at a thermodynamically stable state. To the contrary, if the solvent molecules and acetylene molecules repel each other, then acetylene solubility in the solvent is expected to be insufficient (i.e., having a solubility within acetylene less than that of traditionally used solvents of DMF, acetone and NMP). Acetylene has a chemical structure of C₂H₂ with a triple bond between the carbon atoms. Each of the carbon atoms is covalently bonded to a hydrogen atom, which represents an available center to interact with molecules of the solvent. This hydrogen atom can preferably hydrogen bond with a negative site in the solvent molecule to enable sufficient solubility. Such a negative polarity site can be made available by choosing a polar solvent with an electronegative site provided via a N, O or F atom. The acetylene solubility in the solvent increases with the solvent's potency to hydrogen bond with the acetylene molecule. The Applicants have discovered that the potency of hydrogen bonding can be reliably assessed by a Hansen-solubility interaction parameter, designated as δh, which is defined in the art as the energy from hydrogen bonds between molecules. This parameter signifies how strongly the solvent can form either an intramolecular or intermolecular hydrogen bond. The higher the value of δh, the higher the potency of solvent to form hydrogen bonds therewith. With regards to the present inventive concept, a higher δh for a particular solvent is indicative of greater solubility of acetylene fluid within the solvent molecules. In a preferred embodiment, δh is greater than about 5 MPa^{0.5}.

Another attribute necessary in the present inventive concept is the avoidance, reduction or minimization of O—H, F—H or N—H bonds within the solvent molecule, such that the molecular structure of the solvent contains at least one O, N or F atom not bonded with a H atom within the solvent molecule. Applicants have discovered that an overabundance of O—H, F—H or N—H bonds within the solvent molecule can lead to the solvent molecule having a tendency to self-hydrogen bond with itself, thereby potentially limiting the availability of electronegative sites for hydrogen bonding to occur with an acetylene molecule and thereby create intermolecular hydrogen bonds. By way of example, and not intending to be limiting, if a solvent molecule contains two oxygen atoms, at least one of the two oxygen atoms cannot be bonded to a hydrogen atom within the molecule to reduce the tendency for self-hydrogen bonding within the solvent molecule.

The combination of (i) a sufficiently high δh with (ii) a molecular structure of a solvent that contains at least one O, N or F atom not bonded with a H atom therewithin promotes the ability of the solvent molecule to more effectively interact and solubilize with the acetylene molecule. In other words, the combination of δh greater than about 5 MPa^{0.5} in combination with solvent structure that avoids or minimizes intramolecular H-bonding within the solvent molecule can facilitate H-bonding between the solvent and acetylene molecules.

While providing non-toxicity and effective solubility of the solvent with acetylene fluid are critical, the present inventive concept further requires that the solvent molecule exhibits relatively low vapor pressure to reduces its carryover during dispensing of acetylene. In this regard, the solvents of the present inventive concept have a vapor pressure at 20 degree Celsius (° C.) that is approximately 6 torr or less. Utilizing solvent molecules with lower vapor pressures minimizes contamination of the acetylene that is dispensed to a downstream application. The relatively lower vapor pressure of the solvents of the present inventive concept enables minimal carryover of the solvent during dispensation of acetylene, thereby allowing delivery of high purity acetylene. On the contrary, conventional solvents such as acetone have a vapor pressure of 187 torr at 20° C. which poses large amounts of contaminant risks (see Table 2 below) as a result of a large amount of acetone having a tendency to be withdrawn with the acetylene from the container.

Having described all the necessary attributes of the inventive solvents, Table 1 depicts representative non-limiting examples of solvents in accordance with the principles of the present inventive concept. As can be seen, triethyl phosphate (TEP); dihydrolevoglucosenone (Cyrene); tetraethylene glycol dimethyl ether; acetic anhydride; cyclohexanone; pentoxone; and mesityl oxide are solvents expected to be safer in handling and exhibit sufficient solubility with acetylene fluid within a container. All of the inventive solvents are characterized by an absence of H360 classification; exhibit relatively low vapor pressure of approximately 6 torr or less; have a Hansen-solubility interaction parameter, designated as δh, of greater than about 5 MPa^{0.5}; and a molecular structure that eliminates, reduces or minimizes O—H, F—H or N—H bonds within the solvent molecule, such that the molecular structure of the solvent contains at least one O, N or F atom not bonded with a H atom within the solvent molecule; and additionally whereby no P, B, Ca and Ni atoms are contained in the solvent chemical structure. The combination of these attributes represents a significant improvement and departure over traditional solvents used for storage and delivery of acetylene. Table 2 lists DMF, acetone, and NMP under the caption Prior Art as representative of traditional solvents used to store acetylene. As can be seen, the traditional solvents have one or more deficiencies, such as H360 toxicity and/or unacceptably high vapor pressure. The Hansen solubility factor (δh) values were generated using software commercially available as HSPiP software and with an official site at https://www.hansen-solubility.com/contact.php.

TABLE 1

| | | Dihydrolevo- | Tetraethylene glycol |
|---|---|---|---|
| | Triethyl Phosphate | glucosenone | dimethyl ether |
| Molecular Structure | 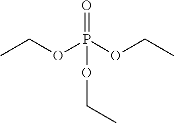 | 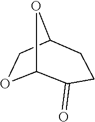 | 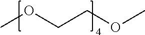 |
| Classified | No | No | No |
| as H360 | | | |
| Vapor | 0.3 | 0.1 | <0.01 |
| pressure @ | | | |
| 20° C. (torr) | | | |
| δh (MPa^{0.5}) | 9.2 | 6.9 | 6.98 |
| | Acetic anhydride | Cyclohexanone | Pentoxone |
| Molecular Structure | 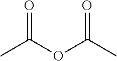 | 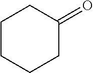 | 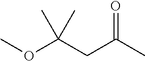 |
| Classified | No | No | No |
| as H360 | | | |
| Vapor | 4 | 2.9 | 2.65 |
| pressure @ | | | |
| 20° C. (torr) | | | |
| δh (MPa^{0.5}) | 10.2 | 5.1 | 5.9 |

| | Mesityl oxide |
|---|---|
| Molecular Structure | 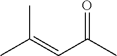 |
| Classified | No |
| as H360 | |
| Vapor | 8.2 |
| pressure @ | |
| 20° C. (torr) | |
| δh (MPa^{0.5}) | 6.2 |

TABLE 2
(Prior Art)

| | | | N-methyl- |
|---|---|---|---|
| | Dimethylformamide | Acetone | 2-pyrrolidone |
| Molecular Structure | 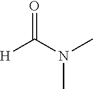 | 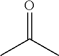 | 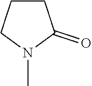 |
| Classified | Yes | No | Yes |
| as H360 | | | |
| Vapor | 3 | 187 | 0.24 |
| pressure @ | | | |
| 20° C. (torr) | | | |
| δh (MPa^{0.5}) | 9.2 | 7 | 6.7 |

It should be understood other solvents not listed in Table 1 are also contemplated by the present inventive concept. For example, the inventive solvents may include, but are not limited to, the following compounds.

### (1) N,N,N′,N′-Tetramethylmethyl-phosphondiamide

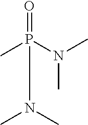

(2) Tetramethylene sulfoxide

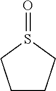

### (3) Tetramethylurea

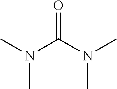

(4) N-Acetyl pyrrolidine

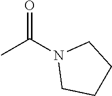

### (5) Tris(N,N-tetramethylene)phosphoramide

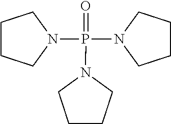 [SMILES: O=P(N1CCCC1)(N1CCCC1)N1CCCC1]

(6) Methyl naphthodioxane

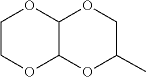

(7) Trimethyl phosphite

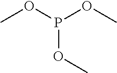

(8) Tetramethyldiamidophosphoryl fluoride

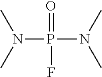

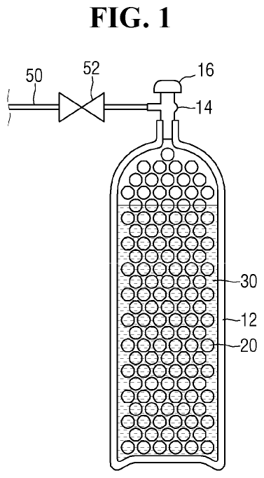

FIGS. 1 to 3 are schematic diagrams illustrating various acetylene fluid supply packages according to certain embodiments of the present inventive concept.

Referring to FIG. 1, the acetylene fluid supply package according to certain embodiments includes a storage container (or pressure vessel) 12 having an interior volume occupied with porous media (or porous filler) 20 (e.g., silica) pre-loaded within the container 12. One or more of the solvents 30 of the present inventive concept are dispersed or loaded into the porous media 20 and around the porous media 20. C₂H₂ is stored by solubilizing C₂H₂ (32) in the solvent 30 to a desired pressure. Typical fill pressure ranges from 200-300 psig at 21° C. A pressure regulating device (52) is installed at the outlet 14 of the cylinder 12 to reduce the outlet pressure to a desired pressure (approximately 15-30 psig) before connecting to flow control devices for ease of operation. A shutoff valve 16 is shown along the top of the container 12. The acetylene fluid is at least partially solubilized within the improved solvent 30.

The outlet 14 may serve as a gate through which acetylene fluid is discharged from or enters the container 12. For example, acetylene fluid may be discharged from the container 12 or introduced into the container 12 through a gas pipe 50 connected to the outlet 14. The shutoff valve 16 is installed at the outlet 14 to selectively open/close the outlet 14, such that the acetylene fluid may be controlled. In certain embodiments, a first valve 52 may be further provided on the gas pipe 50. The first valve 52 may control the amount of the acetylene fluid flowing through the gas pipe 50 and also serve as a pressure regulating device such that cylinder pressure is reduced to a desired level.

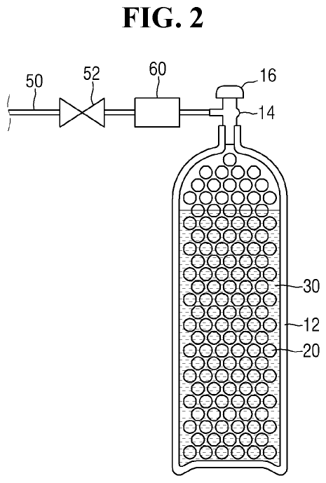

Referring to FIG. 2, the acetylene fluid supply package according to some embodiments includes the container 12 of FIG. 1 with at least a portion of acetylene fluid solubilized within one or more of the inventive solvents 30 that is dispersed within and around the porous media 20 in combination with a solvent trap 60. A cylinder or storage container (12) filled with a porous filler material (20) is loaded with a desired solvent (30). The solvent disperses in the voids within and around the porous filler material. C₂H₂ is stored by solubilizing C₂H₂ in the solvent to a desired pressure. Typical fill pressures range from 200-300 psig at 21° C. The solvent trap 60 is a canister containing an adsorbent material that is installed at the outlet of the cylinder and upstream of pressure regulating device 52. It should be understood that the canister can be loaded with any suitable desired adsorbent media such as activated carbon, zeolite or a metal organic framework which is capable of trapping the inventive solvent that may be passing through it as a result of being withdrawn from the interior volume of the container 12. In this manner, the removal of any carry-over solvent can be achieved, thereby improving the purity of delivered acetylene desired for critical application like deposition of carbon films for electronic device fabrication.

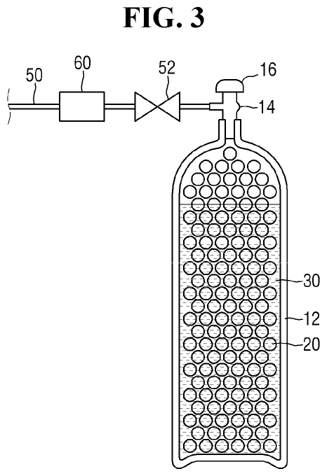

Referring to FIG. 3, the acetylene fluid supply package according to some embodiments includes the solvent trap 60 that is installed downstream of pressure regulating device 52.

It should be understood that FIGS. 1 to 3 represent non-limiting examples of a storage and delivery package with the improved solvents 30, porous media 20 and acetylene. Other configurations to the storage and delivery package are contemplated without departing from the scope of the present inventive concept. For example, the acetylene fluid supply packages of the present disclosure may be of any configuration that is suitable to contain the acetylene fluid during storage and transport conditions, and to discharge the acetylene fluid from the fluid supply package under dispensing conditions. It should be understood that a single solvent 30 may be utilized or a mixture of two or more solvents 30 may be utilized, where the resultant mixture is characterized by each of the attributes required by the present inventive concept as has been discussed hereinbefore. The dispensing conditions may be accommodated by actuating the fluid dispensing assembly to effect dispensing, e.g., by opening of a valve in a valve head of the fluid dispensing assembly of the package.

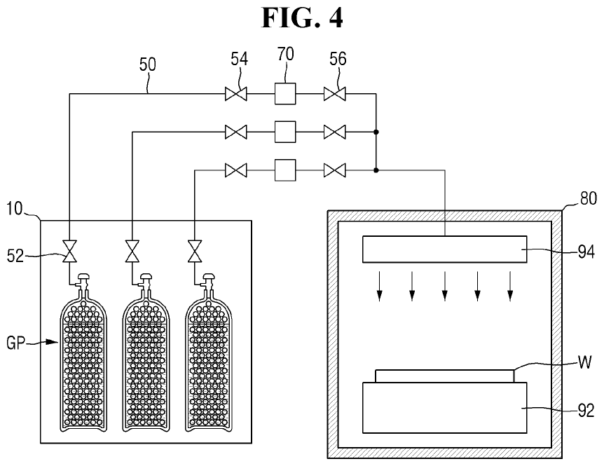

The present inventive concept contemplates various fields of use for the compositions described herein. For example, some methods include but are not limited to chemical vapor deposition, plasma enhanced chemical vapor deposition, beam line ion implantation and plasma immersion ion implantation. One example of the usage of the acetylene delivery package (i.e., acetylene fluid supply package) of the present inventive concept is shown in FIG. 4. FIG. 4 is a schematic diagram illustrating a deposition system including acetylene fluid supply packages according to some embodiments. FIG. 4 shows the use of the acetylene delivery package operably connected to certain process equipment in a process to deposit carbon films for electronic devices manufacturing applications.

Referring to FIG. 4, one or more acetylene delivery packages GP are configured within a gas cabinet 10. The acetylene is withdrawn from either the acetylene delivery package of FIGS. 1 to 3 and then the acetylene is dispensed into the processing chamber 80 via a flow control device 70 that can be configured to establish a flow rate of the acetylene that may range from 0.1 slpm to 10 slpm. The process chamber 80 is preferably maintained at a pressure in the range of 0.1-10 torr. The target substrate W is heated to elevated temperatures in the range of 100° C. to 800° C. to assist in the deposition of high purity carbon films. The process chamber 80 may be equipped with a plasma source to assist in the carbon deposition process. It should be understood that the acetylene delivery package can be operated at other flow rates, temperatures, and pressures.

It further should be understood that multiple acetylene delivery packages as shown in FIG. 1 can be loaded into the gas cabinet 10. The outlet of each of the acetylene delivery packages are connected to dedicated flow control devices 70, each of which route into an inlet of a process chamber 80. The acetylene can be stored at a pressure of up to about 300 psig at 21° C. in each of the delivery packages. Upon actuating the shutoff valve into the open position, a controlled flow of acetylene will dispense from its dedicated container.

It further should be understood that multiple acetylene delivery packages GP may be manifolded together to form a bundle of packages and then the combined flow line is split into different flow lines each connected to a dedicated flow control device 70.

In some embodiments, a platen 92 may be disposed in the process chamber 80. For example, the platen 92 may be disposed in a lower part of the inner space of the process chamber 80. The target substrate W may be loaded on the platen 92, and the platen 92 may support the loaded target substrate W. The platen 92 may be an electrostatic chuck that holds the target substrate W with an electrostatic force, but the present disclosure is not limited thereto.

In some embodiments, a shower head 94 may be disposed in the process chamber 80 and face the platen 92. For example, the shower head 94 may be disposed in an upper part of the inner space of the process chamber 80. The shower head 94 may provide acetylene on the loaded target substrate W. For example, the shower head 94 may be connected to the acetylene delivery packages GP in the gas cabinet 10 by the gas pipe 50. The acetylene discharged from the acetylene delivery packages GP may be moved along the gas pipe 50 to be provided into the process chamber 80 through the shower head 94.

In some embodiments, a second valve 54 may be further provided in the gas pipe 50. The second valve 54 may control the amount of acetylene fluid flowing into the flow control device 70. For example, the second valve 54 may be provided in the gas pipe 50 connecting the first valve 52 to the flow control device 70.

In some embodiments, a third valve 56 may be further provided in the gas pipe 50. The third valve 56 may control the amount of acetylene fluid flowing into the shower head 94. For example, the third valve 56 may be provided in the gas pipe 50 connecting the flow control device 70 to the shower head 94.

The carbon films as deposited can be used for a variety of application including, but not limited to, protective layers over underlying film during subsequent etching process steps, or conductive carbon films for transport of electrons. Many of the applications are sensitive to impurities or unwanted contamination, and as such contamination can adversely affect films properties including their optical properties, electrical properties or robustness in other subsequent processes. In such scenarios, the supply of acetylene stabilized in solvent containing reactive elements can form non-volatile reaction products under deposition conditions, which is undesired. Even a relatively low vapor pressure solvent may transport to the process chamber in varying trace amounts and adversely impact film properties. For this reason, solvents for acetylene that contain metals or inorganic impurities like boron, calcium and nickel is undesired for this application. In this regard, one of the attributes of the present inventive concept is that the chemical structure is characterized by an absence of boron, calcium and nickel.

The ability of the present inventive concept to produce high purity films is an advantage over conventional solvents such as acetone, which serves as a contaminant for several applications described above where a high purity acetylene is required. Acetone serves as a contaminant which can adversely impact the properties of carbon films utilized during fabrication of electronic devices.

As has been described, the present inventive concept presents a novel solvent that exhibits higher non-toxicity that is characterized by an absence of a H₃₆₀ hazard statement code while still maintaining acetylene solubilizing capacity in a manner that allows high purity acetylene product to be withdrawn from a storage and delivery container.

Each of the improved solvents 30 has a different solubilizing capacity for acetylene, which translates into a specific volume expansion of the solvent 30 within cylinder 12. The loading of each of the solvents 30 into cylinder 12 must be determined solvent-by-solvent and takes into account the volume expansion of a particular solvent 30 as a result of the gaseous acetylene dissolving therein, such that sufficient free space of at least about 10% of the cylinder free volume is maintained in the cylinder 12. Additionally, the amount of loading for each of the improved solvents 30 must allow for sufficient acetylene to be dissolved therein without overpressurizing the cylinder 12. Accordingly, the criticality of the loading parameters of each of the improved solvents 30 into cylinder 12 of the present inventive concept is a unique value, as has been experimentally determined by Applicants. For example, the amount of triethyl phosphate (TEP) that can be loaded into cylinder 1 is no greater than about 0.64 kg of TEP per liter of cylinder volume, preferably no greater than about 0.61 kg of TEP per liter of cylinder volume and more preferably, no greater than about 0.58 kg of TEP per liter of cylinder volume.

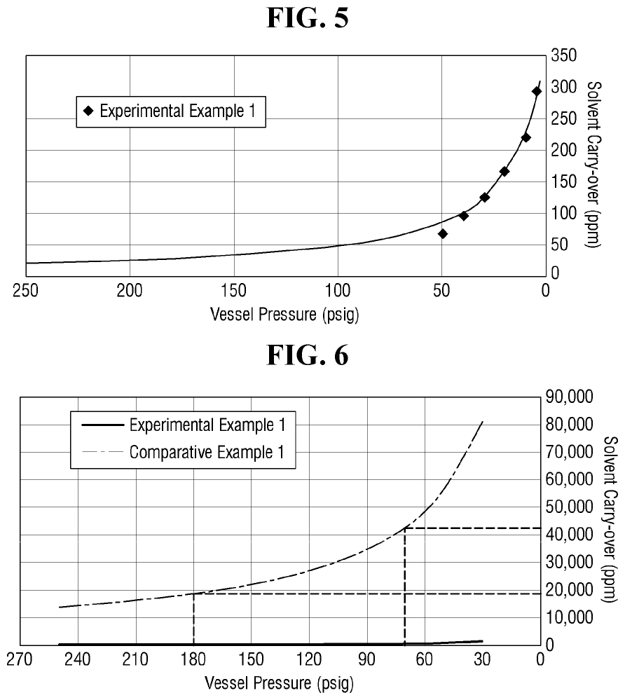

FIGS. 5 to 7 are graphs that illustrate the effect of the acetylene fluid supply packages according to some embodiments. For convenience of description, overlapping parts with those described above with reference to FIGS. 1 to 4 will be briefly described or omitted.

### Experimental Example 1

A pressure vessel filled with porous silica particles was filled with triethyl phosphate as a solvent, and acetylene was dissolved under a fill pressure of 250 psig at 21° C., thereby fabricating an acetylene fluid supply package.

### Comparative Example 1

An acetylene fluid supply package was fabricated in the same manner as described in Experimental Example 1, except that acetone was used as a solvent.

### [Evaluation of Carry-Over]

The solvent carry-over of a fluid discharged from the acetylene fluid supply package fabricated according to Experimental Example 1 was measured and shown in FIG. 5. Also, the solvent carry-over of the fluids discharged from the acetylene fluid supply packages fabricated according to Experimental Example 1 and Comparative Example 1 were measured, and shown in FIG. 6.

Referring to FIGS. 5 and 6, compared with the acetylene fluid supply package prepared according to Comparative Example 1, it can be confirmed that the acetylene fluid supply package fabricated according to Experimental Example 1 shows a significantly reduced solvent carry-over.

For example, when the vessel pressure is approximately 70 psig, unlike the solvent carry-over (that is, acetone carry-over) of the fluid discharged from the acetylene fluid supply package according to Comparative Example 1, which is approximately 42,000 ppm, it can be confirmed that the solvent carry-over (that is, the carry-over of triethyl phosphate) of the fluid discharged from the acetylene fluid supply package according to Experimental Example 1 is significantly reduced to approximately 66 ppm. It can be understood that this is because the vapor pressure of the triethyl phosphate (approximately 0.3 torr at 20° C.) is significantly lower than that of acetone (approximately 187 torr at 20° C.).

[Evaluation of carbon film]

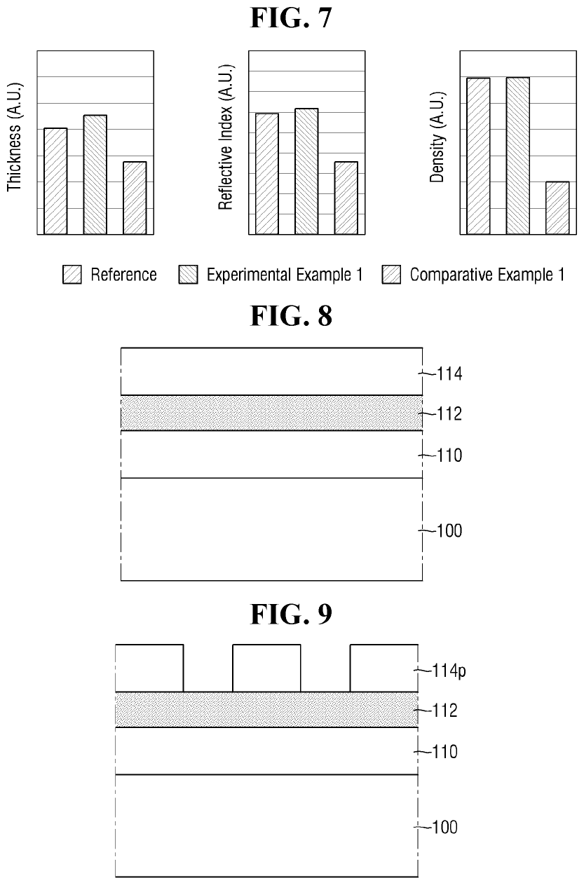

Carbon films were deposited on a wafer using each of the acetylene fluid supply packages fabricated according to Experimental Example 1 and Comparative Example 1, and the physical properties (thickness, reflective index and density) of the deposited carbon films were measured, and shown in FIG. 7. The deposition of the carbon films on the wafer is performed using the deposition system described with reference to FIG. 4. In addition, as a reference of the carbon film deposited according to each of Experimental Example 1 and Comparative Example 1, a carbon film was deposited on a wafer using a pure acetylene gas without solvent carry-over.

Referring to FIG. 7, compared with the carbon film deposited by the acetylene fluid supply package according to Comparative Example 1, it can be confirmed that the carbon film deposited by the acetylene fluid supply package according to Experimental Example 1 exhibits significantly improved physical properties.

Particularly, unlike the carbon film deposited by the acetylene fluid supply package according to Comparative Example 1 having a great difference in physical properties from the reference carbon film, it can be confirmed that the carbon film deposited by the acetylene fluid supply package according to Experimental Example 1 exhibits physical properties similar to the reference carbon film. It can be understood that this is because, as described above, the solvent carry-over (that is, the carry-over of triethyl phosphate) of the fluid discharged from the acetylene fluid supply package according to Experimental Example 1 is significantly lower than that (acetone carry-over) of the fluid discharged from the acetylene fluid supply package according to Comparative Example 1.

As described above, since the solvent has high solubility for acetylene (e.g., approximately 5 MPa^{0.5} or more) and a low vapor pressure (e.g., approximately 6 torr or less), the carry-over of the solvent discharged while being mixed in acetylene may be significantly reduced. In addition, the solvent has low reproductive toxicity and thus is easily applied. Therefore, an acetylene fluid supply package enabling stable acetylene supply may be provided.

Hereinafter, referring to FIGS. 8 to 24, a method of fabricating a semiconductor device according to exemplary embodiments will be described. The following embodiments are merely exemplary, and the present disclosure is not limited by the embodiments.

FIGS. 8 to 12 show intermediate steps of the method of fabricating a semiconductor device according to some embodiments. For convenience of description, overlapping parts with those described above with reference to FIGS. 1 to 7 will be briefly described or omitted.

Referring to FIG. 8, an etch target film 110, a hard mask film 112 and a photoresist film 114 are sequentially formed on a semiconductor substrate 100.

The semiconductor substrate 100 may be bulk silicon or silicon-on-insulator (SOI). Alternatively, the semiconductor substrate 100 may be a silicon substrate, or formed of a different material, for example, silicon germanium, silicon germanium-on-insulator (SGOI), indium antimonide, a lead tellurium compound, indium arsenide, indium phosphide, gallium arsenide, or gallium antimonide, but the present disclosure is not limited thereto. For convenience of description, hereinafter, the semiconductor substrate 100 is described as a silicon substrate.

The etch target film 110 may be stacked on the semiconductor substrate 100. The etch target film 110 may include an insulating material, for example, at least one of silicon oxide, silicon nitride, silicon oxynitride and a combination thereof, but the present disclosure is not limited thereto.

The hard mask film 112 may be stacked on the etch target film 110. The hard mask film 112 may be formed by a deposition process using acetylene as a raw material. The deposition process may include, for example, a chemical vapor deposition (CVD) process, but the present disclosure is not limited thereto. For example, acetylene may be provided from the acetylene fluid supply package described with reference to FIGS. 1 to 3 on the etch target film 110, and the hard mask film 112 may be a carbon-containing layer formed from the provided acetylene. The hard mask film 112 may be an amorphous carbon layer (ACL) formed from acetylene, but the present disclosure is not limited thereto.

The photoresist film 114 may be stacked on the hard mask film 112. The photoresist film 114 may be formed on the hard mask film 112 by a coating process, for example, spin coating, dip coating or spray coating.

Referring to FIG. 9, a photoresist pattern 114p is formed by patterning the photoresist film 114.

For example, an exposure process may be performed on the photoresist film 114. By the exposure process, the photoresist film 114 may be divided into an exposed part and a non-exposed part. Subsequently, a development process of the photoresist film 114 may be performed. When the development process is a positive tone development (PTD) process, a photoresist pattern 114p from which the exposed part is removed and the non-exposed part remains may be formed. When the development process is a negative tone development (NTD) process, a photoresist pattern 114p from which the non-exposed part is removed and the exposed part remains may be formed.

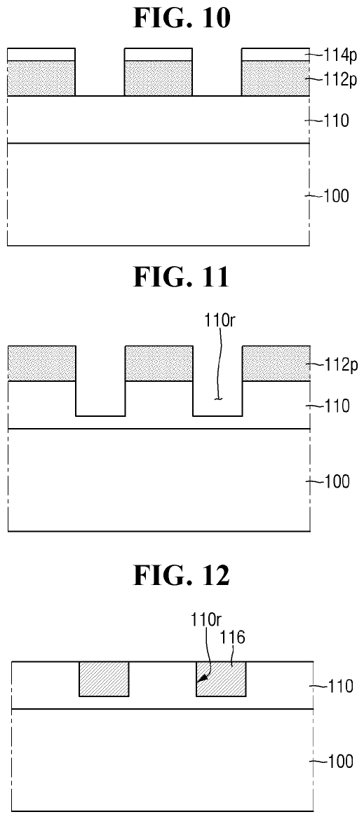

Referring to FIG. 10, a hard mask pattern 112p is formed by patterning the hard mask film 112.

For example, an etching process may be performed using the photoresist pattern 114p as an etch mask. The etching process may include, for example, a dry etching process, but the present disclosure is not limited thereto. Therefore, the hard mask pattern 112p to which the photoresist pattern 114p is transferred may be formed on the etch target film 110.

Referring to FIG. 11, an etching process is performed on the etch target film 110 using the hard mask pattern 112p as an etch mask.

The etching process may include, for example, a dry etching process, but the present disclosure is not limited thereto. As the etching process progresses, a recess 110r may be formed in the etch target film 110. In some embodiments, the depth of the recess 110r may be smaller than the thickness of the etch target film 110. After the etching process is performed on the etch target film 110, the hard mask pattern 112p may be removed.

Referring to FIG. 12, the conductive pattern 116 is formed in the recess 110r.

For example, a conductive film filling the recess 110r may be formed on the etch target film 110. Subsequently, a planarization process may be performed on the conductive film. The planarization process may include, for example, a chemical mechanical polishing (CMP) process, but the present disclosure is not limited thereto. Accordingly, a plurality of conductive patterns 116, which are insulated from each other by the etch target film 110, may be formed.

In some embodiments, the conductive patterns 116 may be used as conductive lines of a semiconductor device. As an example, the conductive pattern 116 may be used as a word line of a volatile memory device such as a dynamic random access memory (DRAM), but the present disclosure is not limited thereto.

As semiconductor devices become increasingly highly integrated, a hard mask film having improved etch selectivity is required. The method of fabricating a semiconductor device according to some embodiments may provide a hard mask film 112 with improved etch selectivity by using the above-described acetylene fluid supply package. Specifically, as described above, the acetylene fluid supply package according to some embodiments may significantly reduce solvent carry-over in a deposition process by using the solvent. Therefore, a high-quality carbon-containing layer (e.g., amorphous carbon layer) may be provided as the hard mask film 112.

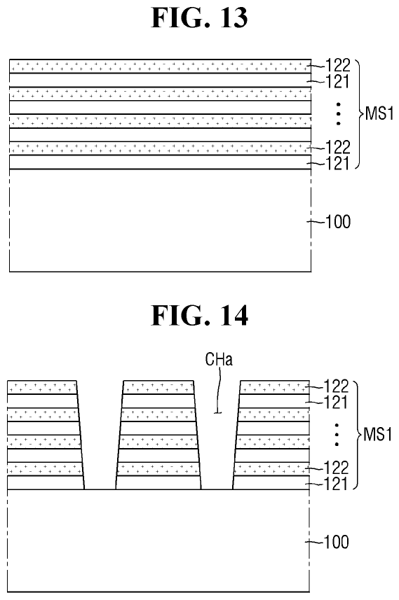

FIGS. 13 to 19 show intermediate steps of the method of fabricating a semiconductor device according to some embodiments. For convenience of description, overlapping parts with those described above with reference to FIGS. 1 to 12 will be briefly described or omitted.

Referring to FIG. 13, a first mold layer MS1 is formed on the semiconductor substrate 100.

The first mold layer MS1 may include a first mold insulating film 121 and a first mold sacrificial film 122, which are alternately stacked on the semiconductor substrate 100.

The first mold insulating film 121 and the first mold sacrificial film 122 may include an insulating material, for example, at least one of silicon oxide, silicon nitride and silicon oxynitride, but the present disclosure is not limited thereto. In some embodiments, the first mold sacrificial film 122 may include a material having an etch selectivity for the first mold insulating film 121. In one example, the first mold insulating film 121 may include a silicon oxide film, and the first mold sacrificial film 122 may include a silicon nitride film.

Referring to FIG. 14, a first hole CHa is formed in the first mold layer MS1.

The first hole CHa may extend in a direction crossing the top surface of the semiconductor substrate 100 (e.g., a vertical direction) to pass through the first mold layer MS1. Accordingly, the first hole Cha may cross a plurality of the first mold insulating films 121 and a plurality of the first mold sacrificial films 122. In some embodiments, the first hole Cha may pass through the first mold layer MS1 to expose a part of the top surface of the semiconductor substrate 100.

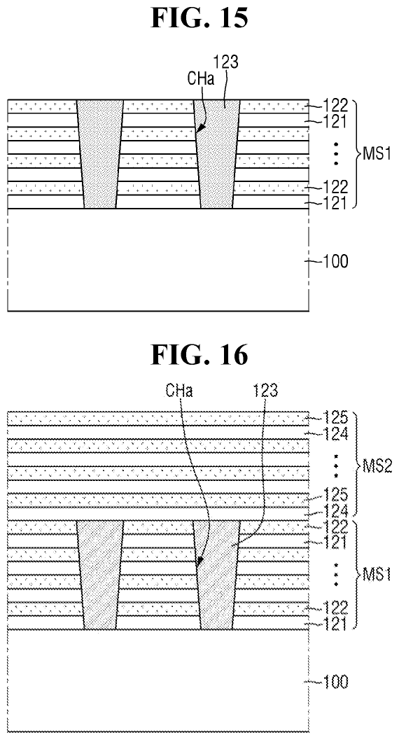

Referring to FIG. 15, a sacrificial pattern 123 is formed in the first hole CHa.

The sacrificial pattern 123 may fill the first hole CHa. The sacrificial pattern 123 may be formed by a deposition process using acetylene as a raw material. The deposition process may include, for example, a chemical vapor deposition (CVD) process, but the present disclosure is not limited thereto. For example, on the first mold layer MS1, acetylene may be provided from the acetylene fluid supply packages described above with reference FIGS. 1 to 3, and the sacrificial pattern 123 may be a carbon-containing layer formed from the provided acetylene. Such a sacrificial pattern 123 may have an etch selectivity for the first mold layer MS1.

Referring to FIG. 16, a second mold layer MS2 is formed on the first mold layer MS1 and the sacrificial pattern 123.

The second mold layer MS2 may include a second mold insulating film 124 and a second mold sacrificial film 125, which are alternately stacked on the semiconductor substrate 100.

The second mold insulating film 124 and the second mold sacrificial film 125 may include an insulating material, for example, at least one of silicon oxide, silicon nitride and silicon oxynitride, but the present disclosure is not limited thereto. In some embodiments, the second mold sacrificial film 125 may include a material having an etch selectivity for the second mold insulating film 124. In some embodiments, the second mold insulating film 124 may include the same material as the first mold insulating film 121, and the second mold sacrificial film 125 may include the same material as the first mold sacrificial film 122. In one example, the second mold insulating film 124 may include a silicon oxide film, and the second mold sacrificial film 125 may include a silicon nitride film.

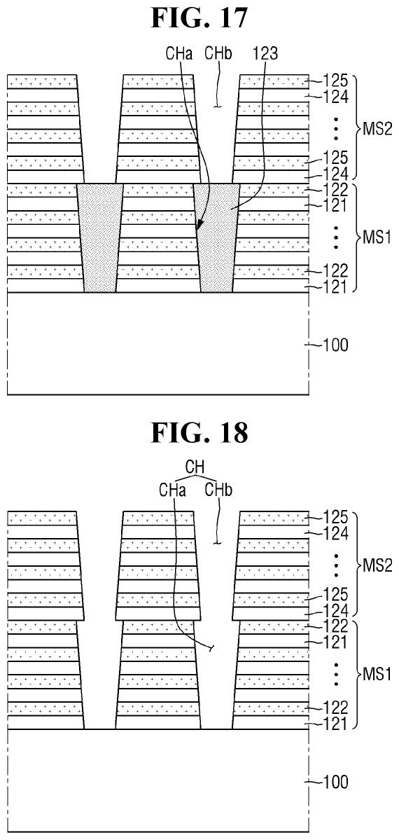

Referring to FIG. 17, a second hole CHb is formed in the second mold layer MS2.

The second hole CHb extends in a direction crossing the top surface of the semiconductor substrate 100 (e.g., a vertical direction) to pass through the second mold layer MS2. Accordingly, the second hole CHb may cross a plurality of the second mold insulating films 124 and a plurality of the second mold sacrificial films 125. In some embodiments, the second hole CHb may pass through the second mold layer MS2 to expose at least a part of the top surface of the sacrificial pattern 123.

Referring to FIG. 18, the sacrificial pattern 123 is selectively removed.

For example, an etching process for removing the sacrificial pattern 123 using the second hole CHb may be performed. The etching process may include, for example, a wet etching process, but the present disclosure is not limited thereto. Since the sacrificial pattern 123 may have an etch selectivity for the first mold layer MS1 and the second mold layer MS2, it may be selectively removed. As the sacrificial pattern 123 is removed, in the first mold layer MS1 and the second mold layer MS2, a through hole CH including the first hole Cha and the second hole CHb, which communicate with each other, may be formed.

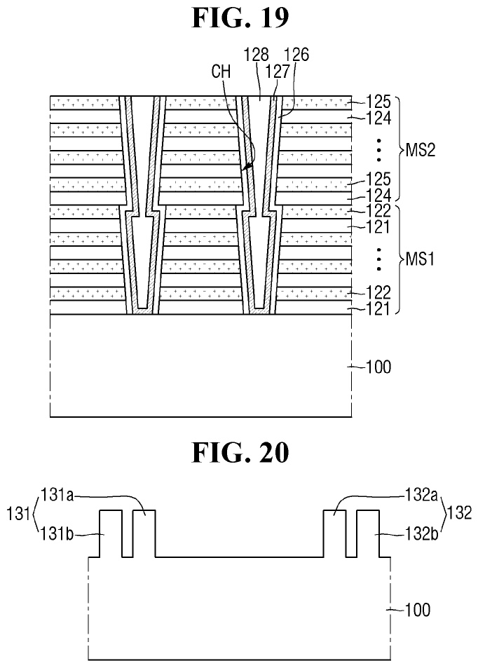

Referring to FIG. 19, a data storage film 126 and a semiconductor film 127 are formed in the through hole CH.

The data storage film 126 and the semiconductor film 127 may be sequentially stacked in the through hole CH.

The data storage film 126 may conformally extend along the profile of the side surface of the through hole CH. The data storage film 126 may include, for example, at least one of silicon oxide, silicon nitride, silicon oxynitride and high-permittivity materials which have higher permittivity than silicon oxide.

The semiconductor film 127 may extend along the top surface of the semiconductor substrate 100 and the side surfaces of the data storage film 126. In some embodiments, the semiconductor film 127 may conformally extend along the profile of the top surface of the semiconductor substrate 100 and the side surfaces of the data storage film 126. The semiconductor film 127 may include, for example, a semiconductor material such as single crystalline silicon, poly crystalline silicon, an organic semiconductor material and a carbon nanostructure, but the present disclosure is not limited thereto.

In some embodiments, the semiconductor film 127 may be used as a channel of the semiconductor device. In one example, the semiconductor film 127 may be used as a channel of a non-volatile memory device such as a NAND flash, but the present disclosure is not limited thereto.

In some embodiments, a filling pattern 128 may be further formed in the through hole CH. The filling pattern 128 may be formed to fill the remaining through hole CH after the data storage film 126 and the semiconductor film 127 have been filled. The filling pattern 128 may include an insulating material, for example, silicon oxide, but the present disclosure is not limited thereto.

As semiconductor devices become increasingly highly integrated, a carbon-containing layer has been suggested as a sacrificial pattern with improved performance. The method of fabricating a semiconductor device according to some embodiments may provide a high-quality carbon-containing layer as the sacrificial pattern 123 using the above-described acetylene fluid supply package.

FIGS. 20 to 23 are drawings illustrating the intermediate steps of the method of fabricating a semiconductor device according to some embodiments. For convenience of description, overlapping parts with those described above with reference to FIGS. 1 to 12 will be briefly described or omitted.

Referring to FIG. 20, a first active pattern 131 and a second active pattern 132, which are spaced apart from each other, are formed on the semiconductor substrate 100.

The first active pattern 131 and the second active pattern 132 may protrude from the top surface of the semiconductor substrate 100. The first active pattern 131 and the second active pattern 132 may be formed by etching a part of the semiconductor substrate 100, and may be epitaxial layers grown from the semiconductor substrate 100.

In some embodiments, the first active pattern 131 may include a first fin pattern 131a and a second fin pattern 131b, which protrude from the top surface of the semiconductor substrate 100 to extend in parallel in one direction, and the second active pattern 132 may include a third fin pattern 132a and a fourth fin pattern 132b, which protrude from the top surface of the semiconductor substrate 100 to extend in parallel in one direction. Here, a distance at which the first fin pattern 131a and the third fin pattern 132a are spaced apart from each other may be longer than that between the first fin pattern 131a and the second fin pattern 131b and that between the third fin pattern 132a and the fourth fin pattern 132b.

In some embodiments, the first active pattern 131 and the second active pattern 132 may be used as channels of the semiconductor device. In one example, the first active pattern 131 and the second active pattern 132 may be used as channels of a field effect transistor (FET) formed in a logic device, but the present disclosure is not limited thereto.

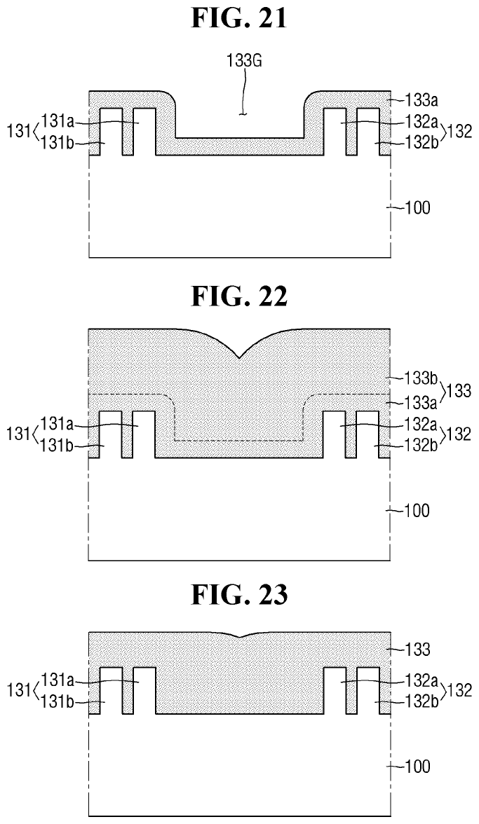

Referring to FIG. 21, a first gap-fill film 133a is formed on the semiconductor substrate 100, the first active pattern 131 and the second active pattern 132.

The first gap-fill film 133a may fill a region between the first fin pattern 131a and the second fin pattern 131b and a region between the third fin pattern 132a and the fourth fin pattern 132b. The first gap-fill film 133a may be formed by a deposition process using acetylene as a raw material. The deposition process may include, for example, a chemical vapor deposition (CVD) process, but the present disclosure is not limited thereto. For example, on the semiconductor substrate 100, the first active pattern 131 and the second active pattern 132, acetylene may be provided from the acetylene fluid supply package described above with reference to FIGS. 1 to 3, and the first gap-fill film 133a may be a carbon-containing layer formed from the provided acetylene. Such a first gap-fill film 133a may fill a part of a region 133G between the first active pattern 131 and the second active pattern 132.

Referring to FIG. 22, a second gap-fill film 133b is formed on the first gap-fill film 133a.

The second gap-fill film 133b may fill the remaining region 133G between the first active pattern 131 and the second active pattern 132 after the first gap-fill film 133a has been filled. The second gap-fill film 133b may be formed by a deposition process using acetylene as a raw material. The deposition process may include, for example, a chemical vapor deposition (CVD) process, but the present disclosure is not limited thereto. For example, on the first gap-fill film 133a, acetylene may be provided from the acetylene fluid supply package described above with reference to FIGS. 1 to 3, and the second gap-fill film 133b may be a carbon-containing layer formed from the provided acetylene. The first gap-fill film 133a and the second gap-fill film 133b may form a gap-fill insulating film 133 filling the region 133G between the first active pattern 131 and the second active pattern 132.

Referring to FIG. 23, an etch back process is performed on the gap-fill insulating film 133.

As the etch back process is performed, the gap-fill insulating film 133 may be adjusted to have a predetermined thickness. Unlike the drawing, the thickness of the gap-fill insulating film 133 may be adjusted to expose at least a part of the first active pattern 131 and at least a part of the second active pattern 132.

As semiconductor devices become increasingly highly integrated, as a gap-fill film with improved gap-fill performance, a carbon-containing layer is suggested. The method of fabricating a semiconductor device according to some embodiments may provide a high-quality carbon-containing layer as a gap-fill insulating film 133 using the acetylene fluid supply package described above.

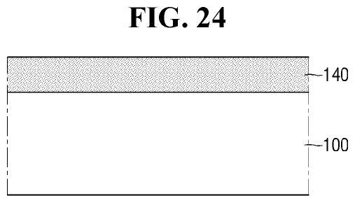

FIG. 24 is an intermediate drawing for describing the method of fabricating a semiconductor device according to some embodiments. For convenience of description, overlapping parts with those described above with reference to FIGS. 1 to 12 will be briefly described or omitted.

Referring to FIG. 24, a graphene layer 140 is formed on the semiconductor substrate 100.

The graphene layer 140 may include graphene formed by a deposition process using acetylene as a raw material. The deposition process may include, for example, a chemical vapor deposition (CVD) process, but the present disclosure is not limited thereto. For example, on the semiconductor substrate 100, acetylene may be provided from the acetylene fluid supply package described above with reference to FIGS. 1 to 3, and the graphene layer 140 may include graphene formed from the provided acetylene.

The graphene layer 140 is illustrated as a single layer, but this is exemplary, and the graphene layer 140 may also be a multi-layer in which a plurality of graphenes are stacked. In addition, the graphene layer 140 is illustrated only as being in contact with the top surface of the semiconductor substrate 100, but this is exemplary, and another material film may be interposed between the semiconductor substrate 100 and the graphene layer 140.

Graphene is in the spotlight as a next-generation material in many fields due to having excellent electrical, mechanical and chemical properties. The method of fabricating a semiconductor device according to some embodiments may provide a high-quality graphene layer 140 using the above-described acetylene fluid supply package.

While it has been shown and described what is considered to be certain embodiments of the inventive concept, it will, of course, be understood that various modifications and changes in form or detail can readily be made without departing from the spirit and scope of the inventive concept. It is, therefore, intended that this inventive concept not be limited to the exact form and detail herein shown and described, nor to anything less than the whole of the inventive concept herein disclosed and hereinafter claimed.

1. An acetylene fluid supply package, comprising
a pressure vessel;
a porous filler in the pressure vessel;
an improved solvent within the porous filler, said solvent solubilizing with acetylene absorbed within the improved solvent;
said improved solvent comprising triethyl phosphate (TEP), said TEP loaded into the pressure vessel in an amount no greater than about 0.64 kg of TEP per liter of volume of the pressure vessel.

2. The acetylene fluid supply package of claim 1, wherein said TEP is loaded into the pressure vessel in an amount no greater than about 0.61 kg of TEP per liter of volume of the pressure vessel.

3. The acetylene fluid supply package of claim 1, wherein said TEP is loaded into the pressure vessel in an amount no greater than about 0.58 kg of TEP per liter of volume of the pressure vessel.

4. The acetylene fluid supply package of claim 1, further comprising the acetylene in a stabilized state at a pressure of up to 300 psig at 21° C.

5. A system comprising at least one acetylene fluid supply package and an acetylene-utilizing process tool in fluid communication with the at least one acetylene fluid supply package, said at least one acetylene fluid supply package, comprising
a pressure vessel;
a porous filler in the pressure vessel;
an improved solvent within the porous filler, said solvent solubilizing with acetylene absorbed within the improved solvent;
said improved solvent comprising triethyl phosphate (TEP), said TEP loaded into the pressure vessel in an amount no greater than about 0.64 kg of TEP per liter of volume of the pressure vessel.
wherein the at least one acetylene fluid supply package is configured to allow a discharge of the acetylene fluid under dispensing conditions; and
further wherein said acetylene-utilizing process tool is configured to receive the acetylene fluid from the at least one acetylene fluid supply package.

6. The system of claim 5, wherein the process tool comprises a chemical vapor deposition tool.

7. The system of claim 5 wherein the at least one at least one acetylene fluid supply package is contained in a gas cabinet.

8. The system of claim 5, wherein said TEP is loaded into the pressure vessel in an amount no greater than about 0.61 kg of TEP per liter of volume of the pressure vessel.

9. The system of claim 5, wherein said TEP is loaded into the pressure vessel in an amount no greater than about 0.58 kg of TEP per liter of volume of the pressure vessel.

10. A method of fabricating a semiconductor device, comprising:
providing a semiconductor substrate; and
forming a carbon-containing layer on the semiconductor substrate using an acetylene fluid supply package,
wherein the acetylene fluid supply package comprises a pressure vessel, a porous filler in the pressure vessel, and a solvent within the porous filler, said solvent solubilizing with acetylene absorbed within the solvent,
the vapor pressure of the solvent is 6 torr or less at 20° C.,
the Hansen solubility factor (δh) of the solvent is 5 Mpa^{0.5} or more, and
the reproductive toxicity of the solvent is lower than that of dimethylformamide (DMF).

11. The method of claim 10, wherein the solvent includes triethyl phosphate (TEP), said TEP loaded into the pressure vessel in an amount no greater than about 0.64 kg of TEP per liter of volume of the pressure vessel.

12. The method of claim 10, wherein the solvent includes at least one of N,N,N′,N′-tetramethylmethyl-phosphondiamide, tetramethylene sulfoxide, tetramethylurea, N-acetyl pyrrolidine, tris(N,N-tetramethylene)phosphoramide, methyl naphthodioxane, trimethyl phosphite and tetramethyldiamidophosphoryl fluoride.

13. The method of claim 10, further comprising:
forming an etch target film on the semiconductor substrate, and
etching the etch target film using the carbon-containing layer as an etch mask.

14. The method of claim 10, further comprising:
forming a mold layer on the semiconductor substrate, the carbon-containing layer is formed in the mold layer; and
removing the carbon-containing layer in the mold layer.

15. The method of claim 10, further comprising:
forming a first active pattern and a second active pattern, which are spaced apart from each other on the semiconductor substrate,
wherein the carbon-containing layer fills at least a part between the first active pattern and the second active pattern.

16. The method of claim 10, wherein the carbon-containing layer includes graphene.
